(19) United States
(12) Patent Application Publication
(10) Pub. No.: US 2012/0119242 A1
(43) Pub. Date: May 17, 2012

(54) LIGHT-EMITTING DEVICE

(75) Inventor: Katsufumi Kondo, Fukuoka-ken (JP)

(73) Assignee: KABUSHIKI KAISHA TOSHIBA, Tokyo (JP)

(21) Appl. No.: 13/052,247

(22) Filed: Mar. 21, 2011

(30) Foreign Application Priority Data
Nov. 12, 2010 (JP) 2010-253710

(51) Int. Cl. H01L 33/46

(52) U.S. Cl. 257/98; 257/E33.069

(57) ABSTRACT

According to one embodiment, a light emitting device includes a support body, a first light emitting portion, a second light emitting portion, and a second reflector. The support body includes a first reflector. The first light emitting portion and the second light emitting portion are provided on the support body and include a light emitting layer. Downward directed light of emission light from the light emitting layer is capable of being reflected upward by the first reflector. The second reflector is interposed between the first light emitting portion and the second light emitting portion, provided on the support body, has a cross-sectional shape expanding downward, and includes a side surface metal layer provided on a side surface of the second reflector.

### CROSS-REFERENCE TO RELATED APPLICATIONS

This application is based upon and claims the benefit of priority from the prior Japanese Patent Application No. 2010-253710, filed on Nov. 12, 2010; the entire contents of which are incorporated herein by reference.

### FIELD

Embodiments described herein relate generally to a light emitting device.

### BACKGROUND

High power light emitting devices are required in illumination devices, display devices, traffic signals, etc.

The light emitting device can include a reflective electrode for reflecting emission light directed downward from its light emitting layer. Then, the upward light extraction efficiency can be increased.

However, the light reflected by the reflective electrode and the light emitted along the surface of the light emitting layer are absorbed while passing through the light emitting layer region where carriers are not sufficiently injected. This causes a problem of being unable to sufficiently increase the optical output.

### BRIEF DESCRIPTION OF THE DRAWINGS

FIG. 1A is a schematic plan view of a light emitting device according to a first embodiment, FIG. 1B is a schematic cross-sectional view taken along line A-A, and FIG. 1C is a schematic cross-sectional view partially enlarged;

FIG. 2A is a schematic plan view of a light emitting device according to a comparative example, FIG. 2B is a schematic cross-sectional view taken along line B-B, and FIG. 2C is a schematic cross-sectional view partially enlarged;

FIG. 3A is a schematic plan view of a light emitting device according to a second embodiment, FIG. 3B is a schematic cross-sectional view taken along line C-C, and FIG. 3C is a schematic cross-sectional view partially enlarged;

FIGS. 4A to 4D are process sectional views of a method for manufacturing a light emitting device according to the second embodiment, where FIG. 4A is a schematic cross-sectional view before wafer bonding, FIG. 4B is a schematic cross-sectional view after wafer bonding, FIG. 4C is a schematic cross-sectional view after forming light emitting portions and second reflectors, and FIG. 4D is a schematic cross-sectional view after forming electrodes;

FIG. 5A is a schematic plan view of a light emitting device according to a third embodiment, FIG. 5B is a schematic cross-sectional view taken along line D-D, and FIG. 5C is a schematic cross-sectional view partially enlarged;

FIG. 6A is a schematic plan view of a light emitting device according to a fourth embodiment, FIG. 6B is a schematic cross-sectional view taken along line F-F, and FIG. 6C is a schematic cross-sectional view partially enlarged; and

FIG. 7A is a schematic plan view of a light emitting device according to a fifth embodiment, FIG. 7B is a schematic cross-sectional view taken along line H-H, and FIG. 7C is a schematic cross-sectional view partially enlarged.

### DETAILED DESCRIPTION

In general, according to one embodiment, a light emitting device includes a support body, a first light emitting portion, a second light emitting portion, and a second reflector. The support body includes a first reflector. The first light emitting portion and the second light emitting portion are provided on the support body and include a light emitting layer. Downward directed light of emission light from the light emitting layer is capable of being reflected upward by the first reflector. The second reflector is interposed between the first light emitting portion and the second light emitting portion, provided on the support body, has a cross-sectional shape expanding downward, and includes a side surface metal layer provided on a side surface of the second reflector.

Embodiments of the invention will now be described with reference to the drawings.

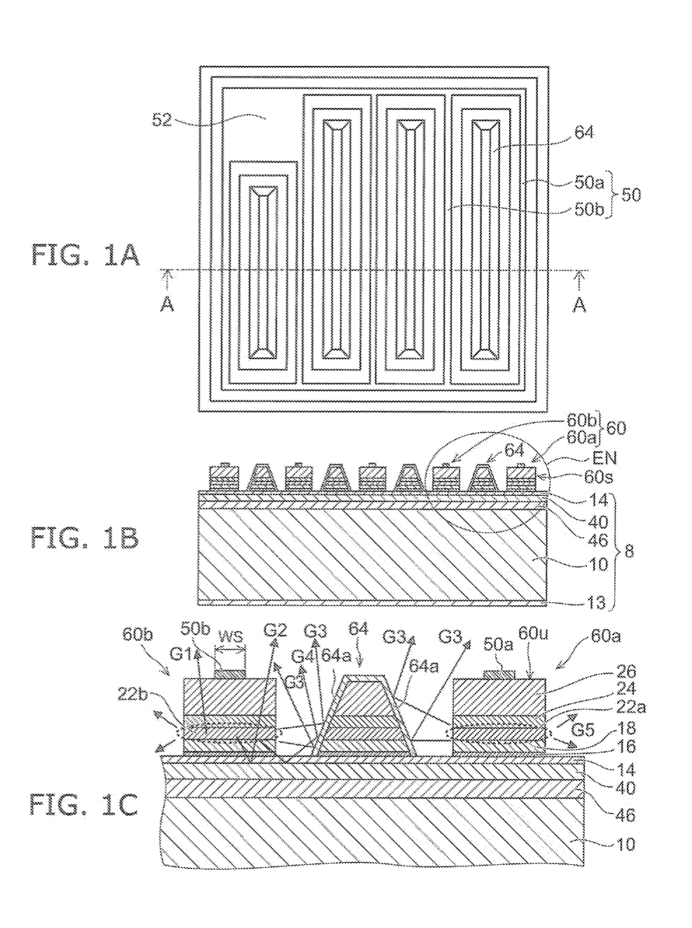

FIG. 1A is a schematic plan view of a light emitting device according to a first embodiment. FIG. 1B is a schematic cross-sectional view taken along line A-A. FIG. 1C is a schematic cross-sectional view partially enlarging the region EN.

The light emitting device includes a support body 8 including a first reflector, first and second light emitting portions 60a and 60b, and a second reflector 64. The support body 8 can include, e.g., a substrate 10, a substrate lower electrode 13 provided on the back surface side of the substrate 10, a bonding electrode 46 provided on the upper surface of the substrate 10, a first reflector (reflective electrode) 40, and a contact layer 14 provided on the reflective electrode 40. The reflective electrode 40 can include at least Au. The reflective electrode 40 may include, e.g., AuZn (containing 0.3% Zn), Ag, and Al on the light reflection side, and Au on the side opposite from the reflection side.

The light emitting portions 60a and 60b have a structure in which, from the first contact layer 14 side, a first current spreading layer 16, a first cladding layer 18, a light emitting layer 22 (22a, 22b), a second cladding layer 24, and a second current spreading layer 26 are stacked. The first contact layer 14, the first current spreading layer 16, and the first cladding layer 18 have a first conductivity type. The second cladding layer 24 and the second current spreading layer 26 have a second conductivity type.

The first light emitting portion 60a is provided on the support body 8 and includes a first light emitting layer 22a. The second light emitting portion 60b is provided on the support body 8 and includes a second light emitting layer 22b. Thus, the light emitting portions 60 (60a, 60b) include at least two light emitting portions. In the first embodiment, a plurality of light emitting portions 60 are parallel to each other. Of the emission light from the light emitting layers 22a and 22b, light G1 is emitted directly upward. The light directed downward includes light G2 reflected upward by the reflective electrode 40.

The second reflector 64 is interposed between the first light emitting portion 60a and the second light emitting portion 60b and provided on the support body 8. Of the emission light from the light emitting layers 22a and 22b, the laterally directed light can be reflected upward by the second reflector 64. In the first embodiment, the second reflector 64 is provided parallel to the plurality of light emitting portions 60 provided parallel to each other.

Furthermore, for instance, the second reflector 64 can include the same stacked structure as the light emitting portions 60a and 60b, and a side surface metal layer 64a. The second reflector 64 has a cross-sectional shape with the width expanding toward the support body 8 located therebelow. The second reflector 64 has a side surface metal layer 64a on its side surface. Of the emission light from the light emitting portions 60a and 60b, the laterally directed light is reflected upward (G3) by the side surface metal layer 64a.

The light directed downward from the light emitting layers 22a and 22b includes light G4. The light G4 is reflected by the reflective electrode 40, then further reflected by the side surface metal layer 64a of the second reflector 64, and directed upward. The light G5 from the side surface 60s of the outermost light emitting portion 60a does not impinge on the second reflector 64, and hence is emitted laterally. If a second reflector 64 is provided in the region along the outer edge of the chip, the wasteful emission light to the lateral side of the chip can be reduced.

On the upper surface 60u of the first light emitting portion 60a, a first thin wire electrode 50a is provided. The first thin wire electrode 50a has a width WS narrower than the width of the upper surface 60u of the first light emitting portion 60a. Furthermore, on the upper surface 60u of the second light emitting portion 60b, a second thin wire electrode 50b is provided. The second thin wire electrode 50b has a width WS narrower than the width of the upper surface 60u of the second light emitting portion 60b. Preferably, the first thin wire electrode 50a and the second thin wire electrode 50b are made parallel. Furthermore, if a fine uneven surface is formed on the upper surface 60u and side surface of the light emitting portion 60, total reflection can be reduced, and the light extraction efficiency can be further increased. In FIGS. 1A to 1C, the first and second thin wire electrodes have a striped configuration.

The width WS of the first and second thin wire electrodes 50a and 50b can be made as thin as e.g. 2 to 20 μm. Then, the amount of emission light blocked by the thin wire electrodes 50 can be reduced. However, wire bonding to the wiring portion of the packaging member is then made difficult. In this case, wire bonding to the packaging member is facilitated by a pad electrode 52 further provided on the support body 8 and connected to the first and second thin wire electrodes 50a and 50b. For instance, as shown in FIGS. 1A to 1C, five slim light emitting portions 60 can be arranged longitudinally. Then, a bonding wire can be connected to a pad electrode 52 connected to each thin wire electrode 50. Here, the electrode layout is not limited to FIGS. 1A to 1C. For instance, the first and second light emitting portions can be provided around a pad electrode. A first thin wire electrode may be located on the upper surface of the first light emitting portion, and a second thin wire electrode may be located on the upper surface of the second light emitting portion. Furthermore, the second reflector can be provided between the first light emitting portion and the second light emitting portion. In this case, the first and second thin wire electrodes may be shaped like a thin circular ring, for instance.

The light emitting portion 60 can be made of materials such as Inₓ(Ga_{y}Al_{1-y})₁₋ₓP (where 0≦x≦1, 0≦y≦1), AlₓGa₁₋ₓAs (0≦x≦1), and InₓGa_{y}Al_{1-x-y}N (where 0≦x≦1, 0≦y≦1, x+y≦1). The materials represented by these composition formulas may include those doped with elements serving as p-type impurity or n-type impurity. The light emitting layer 22 made of these materials can emit light in the visible light wavelength range.

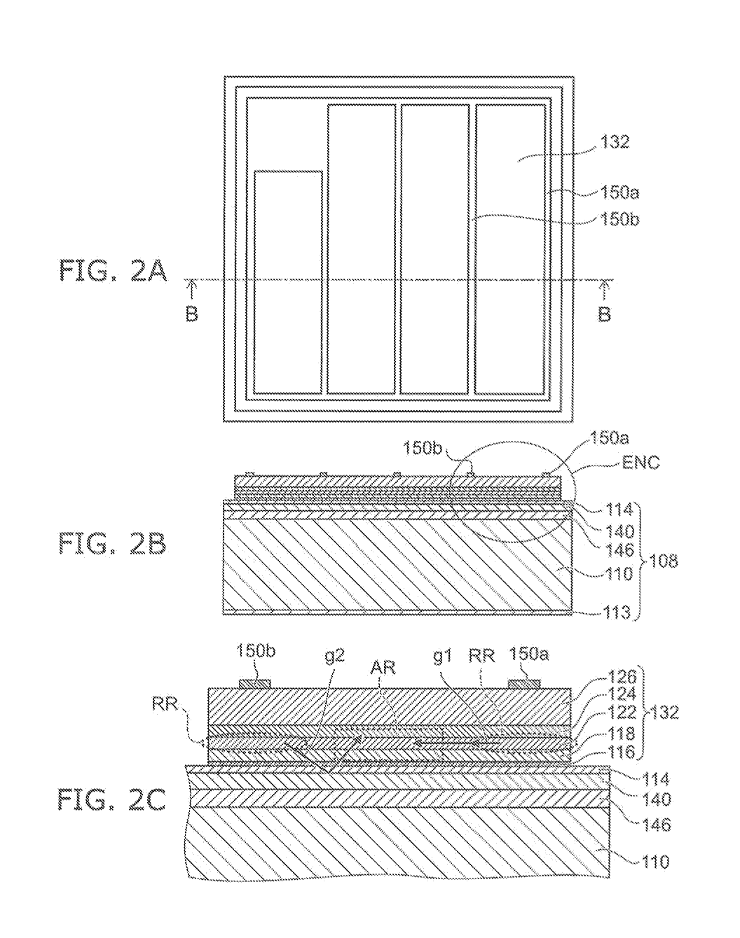

FIG. 2A is a schematic plan view of a light emitting device according to a comparative example. FIG. 2B is a schematic cross-sectional view taken along line B-B. FIG. 2C is a schematic cross-sectional view partially enlarging the region ENC.

The light emitting device includes a support body 108 and a stacked body 132. The support body 108 includes a substrate 110, a substrate lower electrode 113 provided on the back surface side of the substrate 110, a bonding electrode 146 provided on the upper surface of the substrate 110, a reflective electrode 140, and a contact layer 114.

The stacked body 132 includes a current spreading layer 116, a cladding layer 118, a light emitting layer 122, a cladding layer 124, and a current spreading layer 126. Of the emission light from the light emitting layer 122, the light directed downward can be reflected upward by the reflective electrode 140.

As shown in FIG. 2C, carriers are injected from the thin wire electrodes 150a and 150b provided on the stacked body 132 into the stacked body 132. Then, light emitting regions RR occur below the thin wire electrodes 150a and 150b. On the other hand, the region AR interposed between the light emitting regions RR is a low carrier injection region. That is, of the emission light from the light emitting layer 122, part of the laterally traveling light g1 is absorbed in the region AR. Furthermore, part of the light g2 directed downward from the light emitting layer 122 and reflected by the reflective electrode 140 is also absorbed in the region AR.

In the comparative example, the second reflector is not provided. Hence, the laterally directed light is difficult to reflect upward. Furthermore, the optical loss in the region AR inside the light emitting layer 122 increases. Thus, high output power is difficult to achieve. The inventor has found that the emission spectrum is shifted in such a low injection region, because light with shorter wavelengths is absorbed therein more significantly, and components with longer wavelengths are included in a larger proportion in the extracted light. This causes a problem in which the resulting emission spectrum is shifted from the desired emission spectrum.

In contrast, in the first embodiment, the low carrier injection region is removed, and a second reflector 64 is provided. This reduces optical loss inside the light emitting layer. Furthermore, light can be efficiently reflected upward, and high output power can be obtained. Furthermore, the shift of the emission spectrum is suppressed.

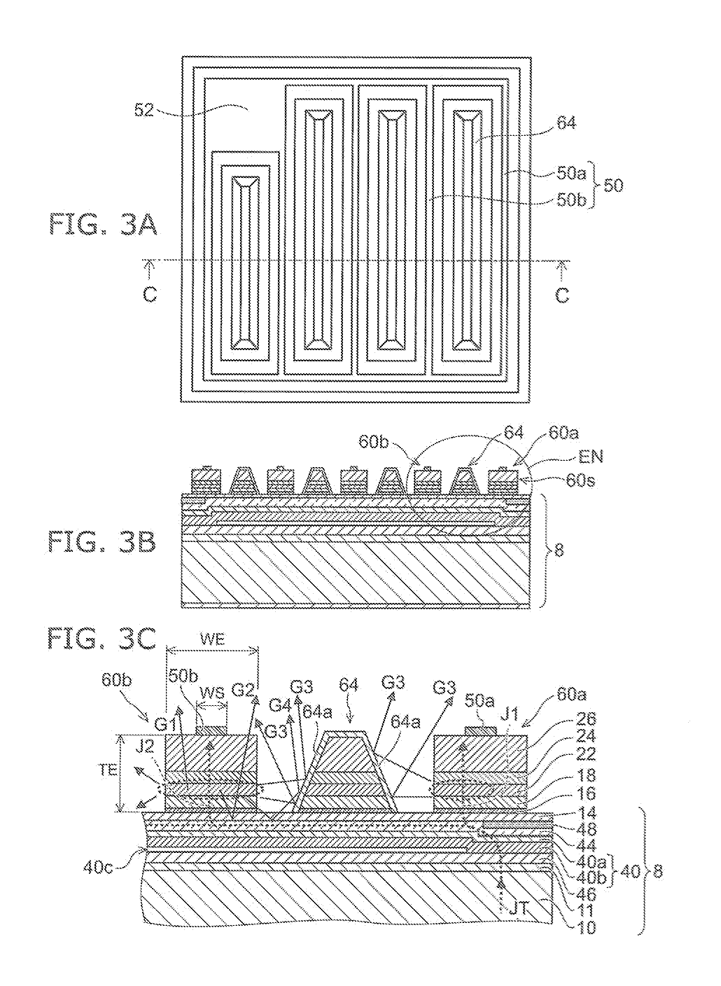

FIG. 3A is a schematic plan view of a light emitting device according to a second embodiment. FIG. 3B is a schematic cross-sectional view taken along line C-C. FIG. 3C is a schematic cross-sectional view partially enlarging the region EN.

The light emitting portion 60 includes Inₓ(Ga_{y}Al_{1-y})₁₋ₓP (where 0≦x≦1, 0≦y≦1) and AlₓGa₁₋ₓAs (0≦x≦1). The first conductivity type is p-type, and the second conductivity type is n-type.

The first contact layer 14 is made of Al_{0.5}Ga_{0.5}As and has a carrier concentration of 1×10¹⁹ cm⁻³ and a thickness of 0.2 μm, for instance. The first current spreading layer 16 is made of In_{0.5}(Ga_{0.3}Al_{0.7})_{0.5}P and has a carrier concentration of 4×10¹⁷ cm⁻³ and a thickness of 0.3 μm, for instance. The first cladding layer 18 is made of In_{0.5}Al_{0.5}P and has a carrier concentration of 2×10¹⁷ cm⁻³ and a thickness of 0.6 μm, for instance. The second cladding layer 24 is made of In_{0.5}Al_{0.5}P and has a carrier concentration of 4×10¹⁷ cm⁻³ and a thickness of 0.6 μm, for instance. The second current spreading layer 26 is made of In_{0.5}(Ga_{0.3}Al_{0.7})_{0.5}P and has a carrier concentration of 5×10¹⁷ cm⁻³ and a thickness of 2 μm, for instance.

The light emitting layer 22 has an MQW (multi-quantum well) structure in which well layers made of e.g. In_{0.5}(Ga_{0.94}Al_{0.06})_{0.5}P and barrier layers made of e.g. In_{0.5}(Ga_{0.4}Al_{0.6})_{0.5}P are alternately arranged. For instance, the width of the well layer is 10 nm, and the width of the barrier layer is 20 nm. Furthermore, the light emitting layer 22 is undoped or lightly doped.

Furthermore, a transparent electrode 44 made of e.g. ITO (indium tin oxide) is provided between the first contact layer 14 and the reflective electrode 40.

On the other hand, on a substrate 10 made of e.g. p-type Si, a substrate upper electrode 11 including Ti and Pt and a bonding electrode 46 are provided in this order. Preferably, the reflective electrode 40 efficiently reflects emission light on one side, and is easily wafer-bonded to the bonding metal 46 of the substrate 10 on the other side.

Electrons injected from the thin wire electrode 50 flow into the light emitting layer 22. On the other hand, the current JT from the reflective electrode 40 flows laterally in the transparent electrode 44 as indicated by the dashed line, and flows into the parallel arranged light emitting portions 60a, 60b, . . . sequentially like J1, J2. Holes injected into the light emitting layer 22 by the current JT recombine with electrons and emit light. That is, the transparent electrode 44 facilitates uniformly injecting the current JT into the light emitting portions 60 arranged in a plurality. Here, the transparent electrode 44 is brought into contact with the contact layer 14 to form non-alloy contact throughout the surface. Thus, the optical loss due to alloys can be reduced.

Furthermore, the outward side surface 60s of the light emitting portion 60a located along the outer edge of the chip is not opposed to the second reflector. If a current blocking layer 48 made of e.g. SiO₂ is provided below the side surface 60s, emission light from the side surface 60s can be reduced, and the light extraction efficiency can be increased. In this case, a step difference occurs in the transparent electrode 44 and the reflective metal 40. This is likely to cause a gap 40c between the reflective metal 40 and the bonding metal 46. However, because the transparent electrode 44 is provided, the current JT is easy to spread laterally.

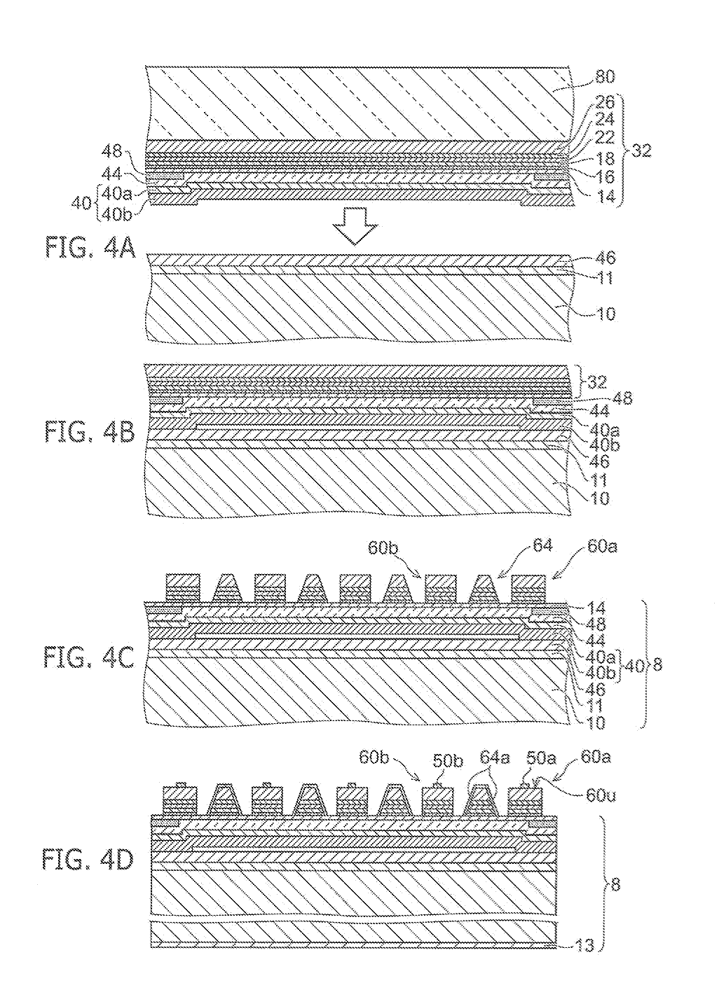

FIGS. 4A to 4D are process sectional views of a method for manufacturing a light emitting device according to the second embodiment. More specifically, FIG. 4A is a schematic cross-sectional view before wafer bonding. FIG. 4B is a schematic cross-sectional view after wafer bonding. FIG. 4C is a schematic cross-sectional view after forming light emitting portions and second reflectors. FIG. 4D is a schematic cross-sectional view after division into chips.

As shown in FIG. 4A, on a crystal growth substrate 80 made of e.g. GaAs, a stacked body 32 is crystal grown by the MOCVD (metal organic chemical vapor deposition) method or MBE (molecular beam epitaxy) method. The stacked body 32 includes, from the crystal growth substrate 80 side, e.g., a second current spreading layer 26, a second cladding layer 24, a light emitting layer 22, a first cladding layer 18, a first current spreading layer 16, and a first contact layer 14.

An insulating film made of e.g. SiO₂ is patterned in the region to be located below the outward side surface 60s of the outermost light emitting portion in a singulated chip. The insulating film serves as a current blocking layer 48. A transparent electrode 44 made of e.g. ITO (indium tin oxide) is formed over the current blocking layer 48 and the first contact layer 14. Subsequently, a reflective electrode 40 including a first film 40a (thickness 0.2 μm) made of e.g. AuZn, Ag, and Al and a second film 40b including Au (thickness 0.6 μm) is formed. If the first film 40a is made of Ag or Al, the reflectance can be made high even for short wavelengths such as blue light. Here, a step difference by the amount of the height of the current blocking layer 48 occurs in the surface of the reflective metal 40.

On the other hand, on a substrate 10 made of e.g. p-type Si, a bonding metal 46 including Au is provided via a substrate upper electrode 11 including e.g. Ti and Pt. The surface of the reflective electrode 40 is laminated with the surface of the bonding metal 46 provided on the substrate 10. They are heated at e.g. 300° C. under pressurization in a vacuum. If the reflective metal 40 and the bonding metal 46 are primarily composed of Au, the wafers are easily bonded together. The step difference produced in the reflective electrode 40 may remain as a gap 40c after wafer bonding. However, no gap occurs below the current blocking layer 48, and a current path is ensured.

Subsequently, as shown in FIG. 4B, the crystal growth substrate 80 is removed by e.g. wet etching or polishing. Furthermore, the stacked body 32 of the region interposed between the light emitting portion 60 and the second reflector 64 is removed by etching so that the center of the current blocking layer 48 is located at the center of the dicing road. The etching depth is selected so as to expose at least the side surface of the light emitting layer 22. For instance, the first contact layer 14 in the stacked body 32 is used as an etching stop layer. This is preferable because the emission light G3 from the side surface is efficiently reflected upward by the side surface metal layer 64a of the second reflector 64. In the case where the width WS of the thin wire electrode 50 is set to 2 to 20 μm, the width WE of the upper surface of the light emitting portion 60 can be set to e.g. 20 to 150 μm. The height TE of the light emitting portion 60 can be set to e.g. 3 to 10 μm.

The slope of the side surface metal layer 64a of the light emitting portion 60 and the second reflector 64 can be controlled by changing the etching liquid or reaction gas in the wet etching process and the dry etching process. In the case where each of them has a different slope, the different slopes can be formed by performing the etching process separately for the light emitting portion 60 and the second reflector 64.

Subsequently, as shown in FIG. 4D, a thin wire electrode 50 is formed on the upper surface 60u of the light emitting portion 60. Furthermore, a pad electrode 52 connected to the thin wire electrode 50 is formed. Moreover, the side surface metal layer 64a of the second reflector 64 is formed. Here, the second reflector 64 may be formed from a metal block by e.g. plating.

Furthermore, a substrate lower electrode 13 is formed on the back surface of the substrate 10. A chip of the light emitting device is completed by dicing at a prescribed position crossing the current blocking layer 48. In the case where the pad electrode 52 is rectangular, the length of the short side being 80 μm or more facilitates wire bonding.

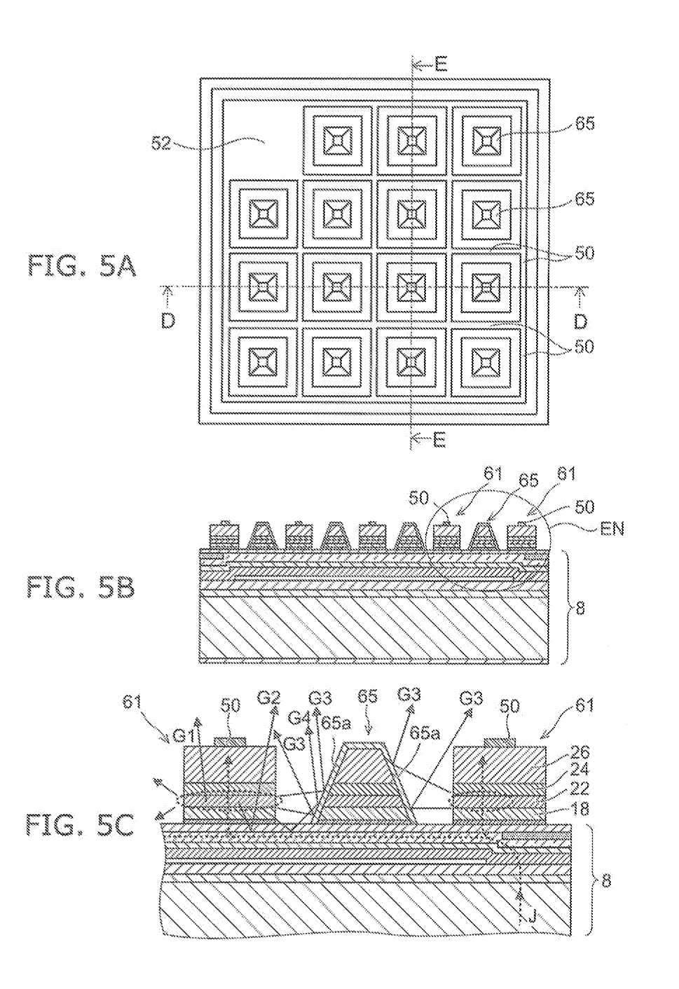

FIG. 5A is a schematic plan view of a light emitting device according to a third embodiment. FIG. 5B is a schematic cross-sectional view taken along line D-D. FIG. 5C is a schematic cross-sectional view partially enlarging the region EN.

The shape of the light emitting portion and the second reflector is not limited to parallel slim rectangles. In the third embodiment, the light emitting portion 61 is arranged in a lattice configuration. Each of second reflectors 65 are surrounded by the lattice-like light emitting portion 61 and provided on the support body 8. That is, the four-side surface metal layer 64a of the second reflector 65 allows emission light from the four opposed side surfaces of the light emitting portion 61 to be reflected upward. Here, the pitch of the light emitting portion 61 in the cross section taken along line E-E orthogonal to line D-D does not need to be equal to the pitch in the cross section taken along line D-D.

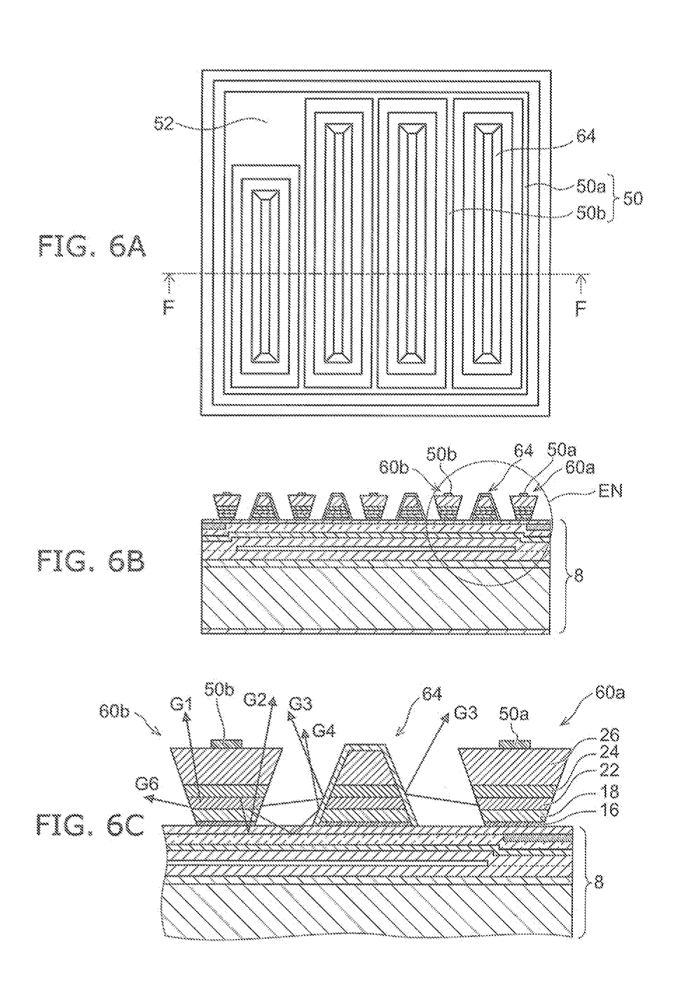

FIG. 6A is a schematic plan view of a light emitting device according to a fourth embodiment. FIG. 6B is a schematic cross-sectional view taken along line F-F. FIG. 6C is a schematic cross-sectional view partially enlarging the region EN.

The first and second light emitting portions 60a and 60b have widths narrowing toward the support body 8. The emission light from the light emitting layer 22, otherwise emitted parallel to the surface of the support body 8, is refracted upward by Snell's law and then emitted (G6). Thus, the light is easily turned upward by the second reflector 64. Furthermore, the spacing between the light emitting portion 60 and the second reflector 64 is easily reduced. Thus, the emitting direction from the light emitting portion 60 and the reflecting direction by the second reflector 64 can be changed. This further facilitates controlling the directional characteristics.

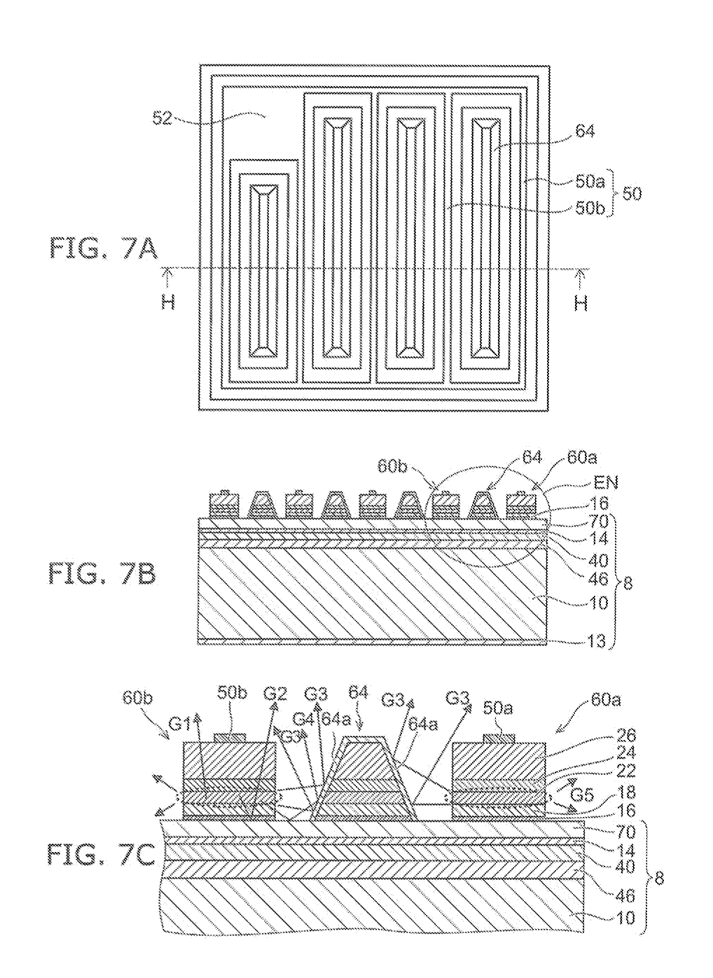

FIG. 7A is a schematic plan view of a light emitting device according to a fifth embodiment. FIG. 7B is a schematic cross-sectional view taken along line H-H. FIG. 7C is a schematic cross-sectional view partially enlarging the region EN.

A first reflector (distributed Bragg reflector layer) 70 is provided between the current spreading layer 16 and the contact layer 14.

In the distributed Bragg reflector (DBR) layer 70, first layers and second layers different in refractive index from the first layers are alternately stacked. The first and second layers can be configured so that the phase is shifted by a half wavelength when the emission light passes through one pair of the first layer and the second layer. Then, the reflected beams constructively interfere with each other with the increase of the number of pairs, and the reflectance can be increased. Furthermore, the first and second layers can be configured so that the phase is shifted by a quarter wavelength when the light passes through each of the first layer and the second layer. This further facilitates increasing the reflectance. Thus, the center wavelength of the DBR layer 70 can be matched with the emission wavelength of the emission light from the light emitting layer 22.

The DBR layer 70 can be configured so that first layers made of p-type In_{0.5}(Ga_{y}Al_{1-y})_{0.5}P (0≦y≦1) and second layers made of p-type In_{0.5}Al_{0.5}P are alternately stacked. The first layer and the second layer have a refractive index difference. The aforementioned number of pairs of the first layer and the second layer is set to within the range of e.g. 20 or more and 40 or less. Also in this case, as in the case of using the reflective electrode 40, the emission light directed downward can be reflected upward.

As described above, the first to fifth embodiments provide a light emitting device in which the optical absorption inside the light emitting layer is reduced and the upward reflectance is increased by the first and second reflector. Such a light emitting device can easily achieve high output power, and can be widely used in illumination devices, display devices, traffic signals, etc.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A light emitting device comprising:
a support body including a first reflector;
a first light emitting portion and a second light emitting portion provided on the support body and including a light emitting layer, downward directed light of emission light from the light emitting layer being capable of being reflected upward by the first reflector; and
a second reflector interposed between the first light emitting portion and the second light emitting portion, provided on the support body, having a cross-sectional shape expanding downward, and including a side surface metal layer provided on a side surface of the second reflector.

2. The device according to claim 1, wherein the first light emitting portion and the second light emitting portion include one of a side surface perpendicular to a surface of the support body and a side surface with a width narrowing downward.

3. The device according to claim 1, further comprising:
a first thin wire electrode provided on an upper surface of the first light emitting portion and having a width narrower than a width of the upper surface of the first light emitting portion;
a second thin wire electrode provided on an upper surface of the second light emitting portion, having a width narrower than a width of the upper surface of the second light emitting portion, and provided parallel to the first thin wire electrode; and
a pad electrode provided on the support body and connected to the first thin wire and the second thin wire electrode.

4. The device according to claim 1, wherein the first reflector is a reflective electrode.

5. The device according to claim 4, wherein the support body includes a substrate, a bonding electrode provided on the substrate, the reflective electrode provided on the bonding electrode, and a contact layer provided on the reflective electrode.

6. The device according to claim 5, wherein the support body further includes a transparent electrode provided between the reflective electrode and the contact layer.

7. The device according to claim 1, wherein the first reflector is a distributed Bragg reflector layer.

8. The device according to claim 7, wherein the support body includes a substrate, a bonding electrode provided on the substrate, and the distributed Bragg reflector layer provided on the bonding electrode.

9. The device according to claim 1, wherein the light emitting layer is made of one of Inₓ(Ga_{y}Al_{1-y})₁₋ₓP (where 0≦x≦1, 0≦y≦1), AlₓGa₁₋ₓAs (0≦x≦1), and InₓGa_{y}Al_{1-x-y}N (where 1≦x≦1, 0≦y≦1, x+y≦1).

10. The device according to claim 8, wherein the support body includes a silicon substrate.

11. A light emitting device comprising:
a support body including a first reflector;
a light emitting portion provided on the support body in a lattice configuration and including a light emitting layer, downward directed light of emission light from the light emitting layer being capable of being reflected upward by the first reflector; and
second reflectors provided on the support body, each of the second reflectors having a side surface metal layer surrounded by the light emitting portion, and having a cross-sectional shape expanding downward.

12. The device according to claim 11, wherein the light emitting portion includes one of a side surface perpendicular to a surface of the support body and a side surface with a width narrowing downward.

13. The device according to claim 11, further comprising:
a thin wire electrode provided on an upper surface of the light emitting portion in a lattice configuration and having a width narrower than a width of the upper surface of the light emitting portion; and
a pad electrode provided on the support body and connected to the thin wire electrode.

14. The device according to claim 11, wherein the first reflector is a reflective electrode.

15. The device according to claim 14, wherein the support body includes a substrate, a bonding electrode provided on the substrate, the reflective electrode provided on the bonding electrode, and a contact layer provided on the reflective electrode.

16. The device according to claim 15, wherein the support body further includes a transparent electrode provided between the reflective electrode and the contact layer.

17. The device according to claim 11, wherein the first reflector is a distributed Bragg reflector layer.

18. The device according to claim 17, wherein the support body includes a substrate, a bonding electrode provided on the substrate, and the distributed Bragg reflector layer provided on the bonding electrode.

19. The device according to claim 11, wherein the light emitting layer is made of one of Inₓ(Ga_{y}Al_{1-y})₁₋ₓP (where 0≦x≦1, 0≦y≦1), AlₓGa₁₋ₓAs (0≦x≦1), and InₓGa_{y}Al_{1-x-y}N (where 0≦x≦1, 0≦y≦1, x+y≦1).

20. The device according to claim 18, wherein the support body includes a silicon substrate.
